(19) United States
(12) Patent Application Publication
(10) Pub. No.: US 2018/0309522 A1
(43) Pub. Date: Oct. 25, 2018

(54) OPTOCOUPLER

(71) Applicant: EVERLIGHT ELECTRONICS CO., LTD., New Taipei City (TW)

(72) Inventors: KUO-CHUN CHIANG, NEW TAIPEI CITY (TW); PO-CHIEH HUANG, NEW TAIPEI CITY (TW); MING-JING LEE, NEW TAIPEI CITY (TW)

(21) Appl. No.: 15/959,102

(22) Filed: Apr. 20, 2018

Related U.S. Application Data
(60) Provisional application No. 62/488,052, filed on Apr. 20, 2017.

(51) Int. Cl. H04B 10/80; H01L 31/173; H01L 31/0203; H01L 31/0232; G02B 6/42

(52) U.S. Cl. CPC H04B 10/802; H01L 31/173; G02B 6/4295; H01L 31/02327; H01L 31/0203

(57) ABSTRACT

An optocoupler is provided, including: at least one light-emitting chip disposed at a first connective region; at least one light-sensing chip disposed at a second connective region; an isolative structure disposed between at least one light-emitting chip and at least one light-sensing chip for isolating an electric field; a first encapsulant covering at least one light-emitting chip, at least one light-sensing chip, first connective region, second connective region and isolative structure; a second encapsulant covering first encapsulant; and a substrate having a recess; wherein first connective region and second connective region are disposed within substrate, at least one light-emitting chip is disposed within recess and electrically connected with first connective region, at least one light-sensing chip is disposed within recess and electrically connected with second connective region, and first encapsulant and second encapsulant are disposed within recess.

### CROSS-REFERENCE TO RELATED APPLICATION

The present disclosure claims priority to U.S. Provisional Patent Application No. 62/488,052 filed Apr. 20, 2017 by Kuo-Chun Chiang et al. and entitled “Optical Device”, which is incorporated herein by reference as if reproduced in their entirety.

### TECHNICAL FIELD

The present disclosure relates to the field of optocouplers.

### BACKGROUND

An optocoupler includes at least one light-emitting chip optically coupled to at least one light-sensing chip via an optical transmission medium. These designs allow for the transfer of information from a circuit containing a light-emitting chip to another circuit containing a light-sensing chip. A high degree of electrical isolation is maintained between the two circuits, since the information passing through the isolative gap is in the form of light, thereby the transmission is unidirectional. For example, a light-sensing chip does not change the operation of a circuit containing a light-emitting chip. This feature is paramount importance since, for example, the transmitter will be driven at a low voltage using a microprocessor or logic gate while an output light-sensing chip can be part of a high voltage direct current (DC) load circuit or alternating current (AC) load circuit. In addition, an optical isolation also prevents an input circuit from being damaged by an output circuit with higher energy.

### SUMMARY

Embodiments of the present disclosure provide an optocoupler. The technical solutions are as follows:

According to first aspect of the present disclosure, an optocoupler is provided. The optocoupler includes:

at least one light-emitting chip disposed at a first connective region for emitting at least one invisible light;

at least one light-sensing chip disposed at a second connective region for receiving the at least one invisible light;

an isolative structure disposed between the at least one light-emitting chip and the at least one light-sensing chip for isolating an electric field;

a first encapsulant covering the at least one light-emitting chip, the at least one light-sensing chip, the first connective region, the second connective region and the isolative structure;

a second encapsulant covering the first encapsulant; and

a substrate having a recess, wherein the first connective region and the second connective region are disposed within the substrate and have conductive characteristic, the at least one light-emitting chip is disposed within the recess and electrically connected with the first connective region being a signal input terminal, the at least one light-sensing chip is disposed within the recess and electrically connected with the second connective region being a signal output terminal, and the first encapsulant and the second encapsulant are disposed within the recess.

According to a first implementation form of the first aspect, the isolative structure includes at least one convex portion and/or at least one concave portion disposed on the recess, wherein a height of the at least one convex portion is not greater than one-half of a height of the first encapsulant and a height of the at least one concave portion is not greater than one-half of a thickness of the substrate.

According to a second implementation form of the first aspect, the recess comprises a bottom surface and a side surface provided with a reflective layer, wherein the side surface surrounds the bottom surface, and the at least one light-emitting chip and the at least one light-sensing chip are disposed at the bottom surface.

According to a third implementation form of the first aspect, wherein the first encapsulant is formed of a highly transparent material comprising polyimide (PI) or silicone; the second encapsulant is formed of a reflective material comprising Epoxy; a material of the substrate is a non-metal material comprising a silicon substrate or a glass substrate; the at least one light-emitting chip comprises an Infrared Light-emitting Diode (LED), a gallium nitride (GaN) base LED, an aluminum gallium arsenide (AlGaAs) LED or a gallium arsenide phosphide (GaAsP) LED; and the at least one light-sensing chip comprises a photo diode, a photo transistor, a photo darlington transistor, a photo tryristor, a photo bidirectional thyristor, or a photo integrated circuit.

According to a fourth implementation form of the first aspect, when the isolative structure includes the at least one convex portion and the at least one concave portion, the at least one convex portion is adjacent to the at least one concave portion.

According to a fifth implementation form of the first aspect, wherein cross-sectional shapes of the at least one convex portion and the at least one concave portion are triangles, quadrangles, or polygons.

According to a sixth implementation form of the first aspect, when the isolative structure includes the at least one convex portion and the at least one concave portion, the at least one convex portion is at least one secondary convex portion disposed within the at least one concave portion.

According to second aspect of the present disclosure, an optocoupler is provided. The optocoupler includes:

at least one light-emitting chip disposed at a first connective region for emitting at least one invisible light;

at least one light-sensing chip disposed at a second connective region for receiving the at least one invisible light;

an isolative structure disposed between the at least one light-emitting chip and the at least one light-sensing chip for isolating an electric field, wherein the isolative structure includes a connective portion and an isolative portion, and wherein the isolative structure is connected to the first connective region and the second connective region via the connective portion in such a way that the isolative portion disposed at the connective portion is located between the light-emitting chip and the light-sensing chip;

a first encapsulant covering the at least one light-emitting chip, the at least one light-sensing chip, the first connective region, the second connective region and the isolative structure; and

a second encapsulant covering the first encapsulant.

According to a first implementation form of the second aspect, the connective portion is made of an adhesive material, and the isolative portion is made of a transparent isolative material comprising polyimide.

According to a second implementation form of the second aspect, the isolative portion is perpendicularly disposed at the connective portion, and a perpendicular height of the isolative portion extending from the connective portion is not greater than a thickness of the first encapsulant, and the isolative portion is a cube or a cone.

According to a third implementation form of the second aspect, the isolative portion is obliquely disposed at the connective portion.

According to a fourth implementation form of the second aspect, the connective portion further comprises a first connective portion and a second connective portion, wherein the isolative portion is disposed between the first connective portion and the second connective portion in advance, wherein the first connective portion and the second connective portion are respectively connected to the first connective region and the second connective region in such a way that the isolative portion is located between the light-emitting chip and the light-sensing chip, and wherein the first connective portion, the second connective portion and the isolative portion are integrally molded in sequence.

According to a fifth implementation form of the second aspect, the first encapsulant covers the first connective portion, the light-emitting chip, the second connective portion, the light-sensing chip and the isolative structure to form an elliptical structure, wherein the light-emitting chip and the light-sensing chip are respectively disposed at two focuses of the elliptical structure of the first encapsulant.

According to a sixth implementation form of the second aspect, the optocoupler further includes a third encapsulant made of a light-transparent material for covering one of the light-emitting chip or the light-sensing chip, so that the oblique isolative portion is disposed at the third encapsulant simultaneously, wherein the first encapsulant covers the third encapsulant.

According to a seventh implementation form of the second aspect, the isolative portion formed in advance is a V-shaped structure, and perpendicular to the first connective portion and the second connective portion.

### BRIEF DESCRIPTION OF DRAWINGS

To make the technical solutions in the embodiments of the present disclosure clearer, the accompanying drawings for illustrating the embodiments of the present disclosure are briefly described below. Apparently, the accompanying drawings are only some embodiments of the present disclosure, and persons of ordinary skill in the art may derive other drawings from such accompanying drawings without creative efforts.

FIG. 1 is a cross-sectional view of an optocoupler according to an embodiment of the present disclosure;

FIG. 2 is a cross-sectional view of another optocoupler according to an embodiment of the present disclosure;

FIG. 3 is a cross-sectional view of another optocoupler according to an embodiment of the present disclosure;

FIG. 4 is a cross-sectional view of an optocoupler according to a further embodiment of the present disclosure;

FIG. 5A is a cross-sectional view of an optocoupler according to a further embodiment of the present disclosure;

FIG. 5B is a top view of an optocoupler according to a further embodiment of the present disclosure;

FIG. 6A is a cross-sectional view of an optocoupler according to a further embodiment of the present disclosure;

FIG. 6B is a top view of an optocoupler according to a further embodiment of the present disclosure;

FIG. 7A is a cross-sectional view of an optocoupler according to a further embodiment of the present disclosure;

FIG. 7B is a top view of an optocoupler according to a further embodiment of the present disclosure;

FIG. 8A is a cross-sectional view of an optocoupler according to a further embodiment of the present disclosure;

FIG. 8B is a top view of an optocoupler according to a further embodiment of the present disclosure;

FIG. 9A is a cross-sectional view of an optocoupler according to a further embodiment of the present disclosure;

FIG. 9B is a top view of an optocoupler according to a further embodiment of the present disclosure;

FIG. 10 is a cross-sectional view of an optocoupler according to a further embodiment of the present disclosure;

FIG. 11 is a cross-sectional view of an optocoupler according to a further embodiment of the present disclosure;

FIG. 12 is a cross-sectional view of an optocoupler according to a further embodiment of the present disclosure;

FIG. 13 is a cross-sectional view of an optocoupler according to a further embodiment of the present disclosure;

FIG. 14 is a cross-sectional view of an optocoupler according to a further embodiment of the present disclosure;

FIG. 15 is a cross-sectional view of an optocoupler according to a further embodiment of the present disclosure;

FIG. 16 is a cross-sectional view of an optocoupler according to a further embodiment of the present disclosure;

FIG. 17 is a cross-sectional view of an optocoupler according to a further embodiment of the present disclosure;

FIG. 18 is a cross-sectional view of another optocoupler according to an embodiment of the present disclosure;

FIG. 19 is a cross-sectional view of another optocoupler according to a further embodiment of the present disclosure;

FIG. 20 is a cross-sectional view of another optocoupler according to a further embodiment of the present disclosure.

### DESCRIPTION OF EMBODIMENTS

To make the objectives, technical solutions, and advantages of the present disclosure clearer, the embodiments of the present disclosure will be described below in further detail with reference to the accompanying drawings.

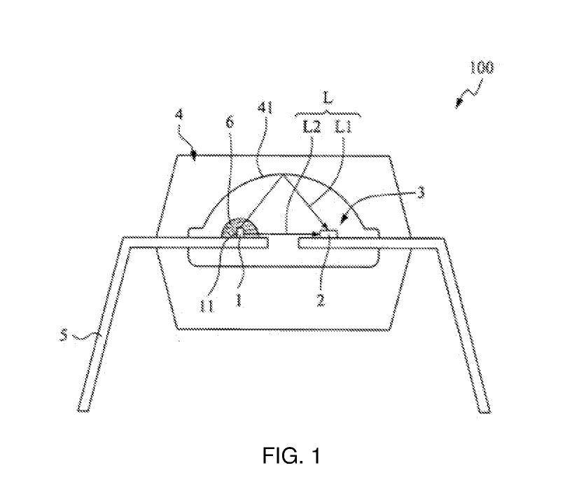

Referring to FIG. 1, an optocoupler 100 (a flat type optocoupler) is provided, including a light-emitting chip 1, a light-sensing chip 2, a transparent inner encapsulant body 3, an outer encapsulant body 4, and at least two conductive frames 5. One surface 11 of the light-emitting chip 1 is covered with a light-transparent sealant 6. The light-emitting chip 1 is disposed at a conductive frame 5 and is electrically connected to the conductive frame 5 for emitting a light L. The light-sensing chip 2 is disposed at another conductive frame 5 and is electrically connected to the conductive frame 5 for receiving the light L. The transparent inner encapsulant body 3 has a dome cover 41 and covers the light-emitting chip 1 and a light-sensing chip 2, and the outer encapsulant body 4 covers the transparent inner encapsulant body 3. The light L emitted by the light-emitting chip 1 is reflected by the dome cover 41 to be received by the light-sensing chip 2.

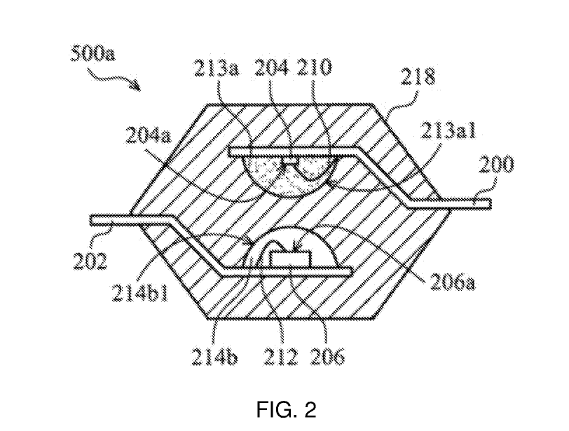

Referring to FIG. 2, another optocoupler package 500a (a face-to-face optocoupler) is provided. The light-emitting chip 204 is fixed at a first conductive frame 200 and electrically connected to the first conductive frame 200 through a conductive wire 210. The light-sensing chip 206 opposite to the light-emitting chip 204 is fixed at the second conductive frame 202 and is electrically connected to the second conductive frame 202 through a conductive wire 212. An illumination surface 204a of the light-emitting chip 204 faces toward a light-sensing surface 206a of the light-sensing chip 206. The isolative material 213a is disposed at the first conductive frame 200. The isolative material 213a fully covers the illumination surface 204a and a sidewall surface of the light-emitting chip 204, and covers a portion of a surface of the first conductive frame 200. Additionally, the isolative material 214b is disposed at the second conductive frame 202. The isolative material 214b covers the light-sensing surface 206a and a sidewall surface of the light-sensing chip 206. Also, the isolative material 214b covers a portion of a surface of the second conductive frame 202. The light-sensing chip 206 is configured to receive the light emitted by the light-emitting chip 204.

However, the technical problem of the above optocoupler is that the closer the distance between two metal conductive frames is or the larger the overlap area of two metal conductive frames is, the larger the capacitance value is and the lower the common mode rejection ratio (CMRR) is, thereby electrical properties of the optocoupler are affected and can not meet application requirements.

Moreover, because the optocoupler is an element that converts an electrical signal into an optical signal by a light-emitting chip, and receives the optical signal and subsequently converts the received optical signal back to an electrical signal by a light-sensing chip, such conversion is a security mechanism ensuring the electrical isolation of an input terminal and an output terminal. However, in an integrated circuit chip, there is another factor that will affect the security mechanism, which is a common mode transient mechanism. The creation of this mechanism is as follows: because if there is a drastic voltage change between an input and an output, for the chip at the output terminal, opening of the chip may lead to an occurrence of an output due to the drastic voltage change. Therefore, in the integrated circuit type optocoupler element, measurement to such parameter of common mode transient suppression (CMRI) is conducted. How to enhance the CMRI becomes technical problem to be solved by the skilled person.

The above relevant technics is merely relevant information of the present invention, rather than the necessary prior art technics.

In order to solve the above problem, the present disclosure provides an optocoupler having an isolative structure. The electrical isolation is improved by increasing a creepage distance (Creepage Distance) and an isolative distance (Clearance), wherein the creepage distance refers to the shortest distance from an electrical signal input terminal (a light-emitting chip) to an electrical signal output terminal (a light-sensing chip) along a surface of an isolative material, wherein the isolative distance refers to the shortest distance from the input terminal to the output terminal in the air.

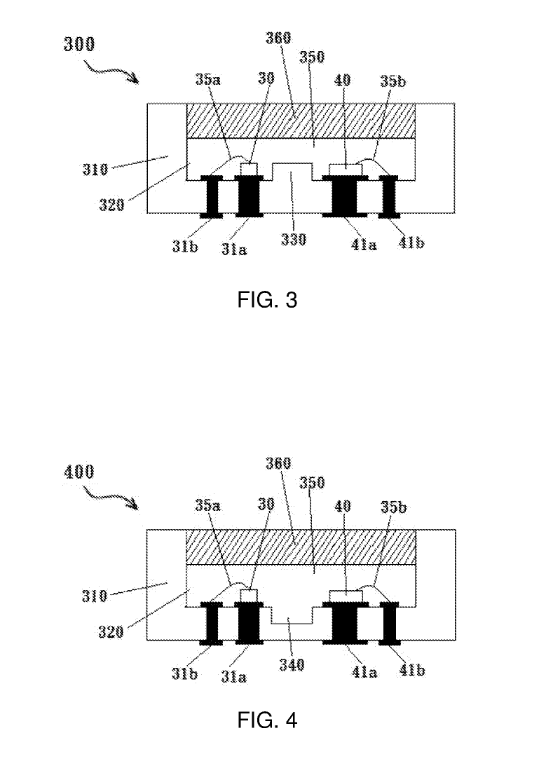

Referring to FIG. 3, the embodiment of the present disclosure provides an optocoupler including:

at least one light-emitting chip 30 disposed at a first connective region (31a, 31b) for emitting at least one invisible light;

at least one light-sensing chip 40 disposed at a second connective region (41a, 41b) for receiving the at least one invisible light;

an isolative structure disposed between the at least one light-emitting chip 30 and the at least one light-sensing chip 40 for isolating an electric field;

a first encapsulant 350 covering the at least one light-emitting chip 30, the at least one light-sensing chip 40, the first connective region (31a, 31b), the second connective region (41a, 41b) and the isolative structure;

a second encapsulant 360 covering the first encapsulant 350; and

a substrate 310 having a recess 320;

wherein the first connective region (31a, 31b) and the second connective region (41a, 41b) are disposed within the substrate 310 and having conductive characteristic, the at least one light-emitting chip 30 is disposed within the recess 320 and electrically connected with the first connective region (31a, 31b) being a signal input terminal, the at least one light-sensing chip is disposed within the recess 320 and electrically connected with the second connective region (41a, 41b) being a signal output terminal, and the first encapsulant 350 and the second encapsulant 360 are disposed within the recess 320.

Specifically, the recess 320 of the substrate 310 includes a bottom surface and a side surface, wherein the side surface surrounds the bottom surface, and the at least one light-emitting chip 30 and the at least one light-sensing chip 40 are disposed at the bottom surface. The material of the substrate may be a non-metal material and includes a silicon substrate or a glass substrate. The first encapsulant 350 fully covers the at least one light-emitting chip 30 and the at least one light-sensing chip 40, and fills a portion of the recess 320, and has high light transmittance, thereby increasing the light coupling efficiency of the optocoupler 300, and has a function of protecting the at least one light-emitting chip 30 and the at least one light-sensing chip 40. For example, a material of the first encapsulant 350 can be polyimide (PI) or silicone. The second encapsulant 360 fills the entire recess 320 and surrounds the first encapsulant 350. In an embodiment of the present disclosure, a material of the second encapsulant 360 is different from the material of the first encapsulant 350. For example, the material of the second encapsulant 360 includes epoxy, which has characteristics of, for example, high light reflectivity, water blocking property, gas barrier property, isolative property, mechanical strength, and etc. The at least one light-emitting chip 30 includes an infrared light-emitting diode (LED), a gallium nitride (GaN) base LED, an aluminum gallium arsenide (AlGaAs) LED or a gallium arsenide phosphide (GaAsP) LED; and the at least one light-sensing chip 40 includes a photo diode, a photo transistor, a photo darlington transistor, a photo tryristor, a photo bidirectional thyristor, or a photo integrated circuit.

In the present embodiment, the creepage distance between the light-emitting chip and the light-sensing chip is improved by providing the isolative structure between at least one light-emitting chip and at least one light-sensing chip, so as to improve the conductive and electrical isolative function. Meanwhile, the problem of the high capacitance value and the low common-mode rejection ratio of the existing optocoupler due to the overlap of the metal conductive frames is solved by providing the light-emitting chip and the light-sensing chip within the recess 320 of a non-metal substrate, thereby enabling the optocoupler to have the characteristics of simplified process, high optical coupling efficiency and high CMRR.

Optionally, referring to FIGS. 3 and 4, the isolative structure can be the at least one convex portion 330 disposed in the recess 320 as shown in FIG. 3 or the at least one concave portion 340 disposed in the recess 320 as shown in FIG. 4. In a preferred embodiment, the height of the at least one convex portion 330 does not block the light reflection path. The light reflection refers to a path along which the light emitted by the at least one light-emitting chip after being reflected by the second encapsulant arrives at the at least one light-sensing chip. In a preferred embodiment, a height of the at least one convex portion 330 is not greater than one-half of a height of the first encapsulant 350 and a height of the at least one concave portion 340 is also not greater than one-half of a thickness of the substrate 310, thereby preventing the substrate from being broken down during the manufacturing of the at least one concave portion.

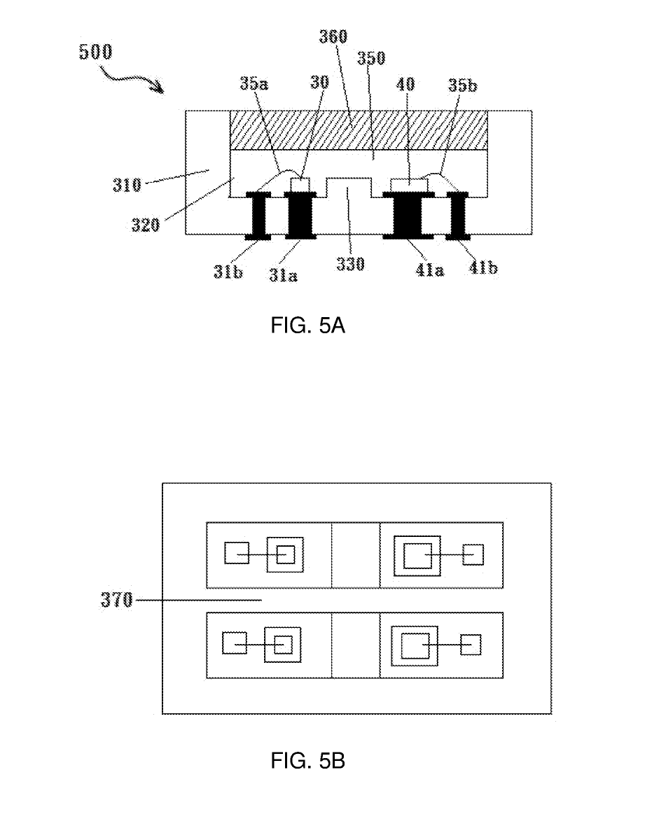

Optionally, referring to FIGS. 5A and 5B, the optocoupler 500 is a combination of a plurality of recesses 320 (not limited to two recesses), wherein each recess 320 is isolated by a stop wall 370 that has the capability of preventing crosstalk between recesses, wherein each recess 320 can accommodate one light-emitting chip 30 and one light-sensing chip 40.

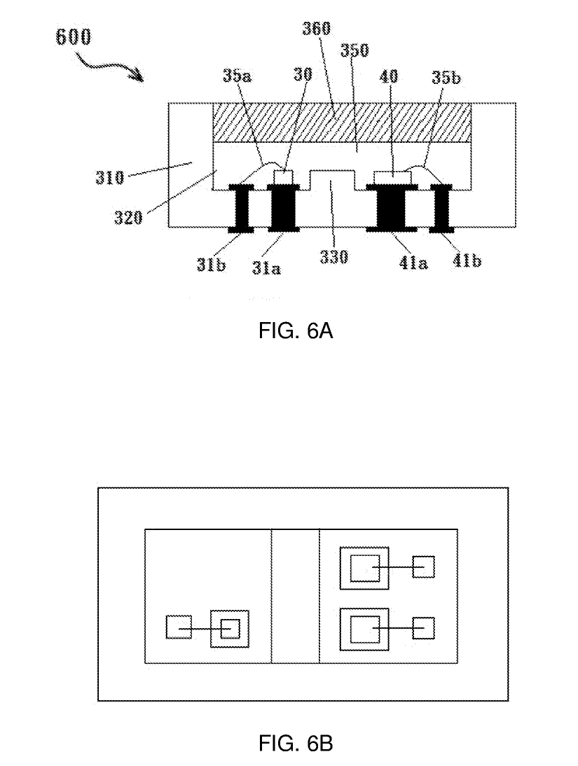

Optionally, referring to FIGS. 6A and 6B, the optocoupler 600 is a combination in which a single light-emitting chip 30 controls and corresponds to a plurality of light-sensing chips 40 (not limited to two light-emitting chips), it has the capability of controlling a plurality of signal output terminals via a single signal input terminal, wherein the position of the connective region shown by FIG. 6B is merely example, which does not limit to the position shown by FIG. 6B.

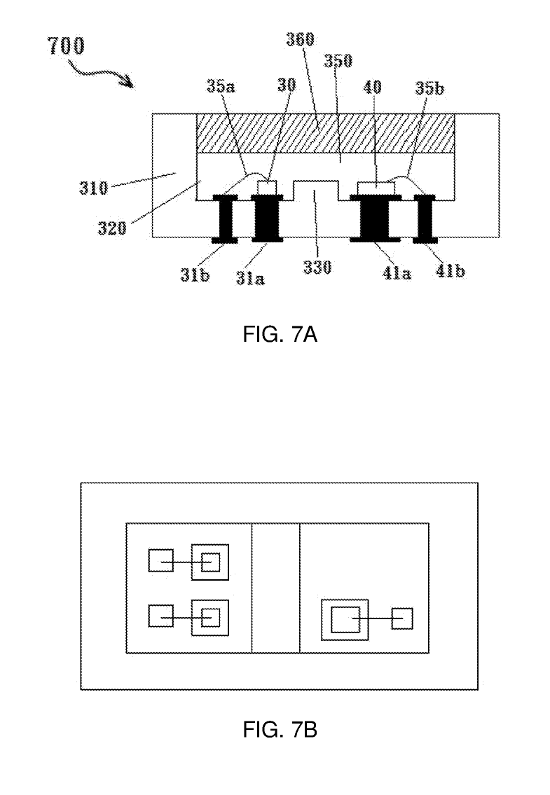

Optionally, referring to FIGS. 7A and 7B, the optocoupler 700 is a combination in which a plurality of light-emitting chips 30 control and correspond to a single light-sensing chip 40 (not limited to two light-emitting chips), it has the capability of controlling a single signal output terminal via a plurality of signal input terminals, wherein the position of the connective region shown by FIG. 7B is merely example, which does not limit to the position shown by FIG. 7B.

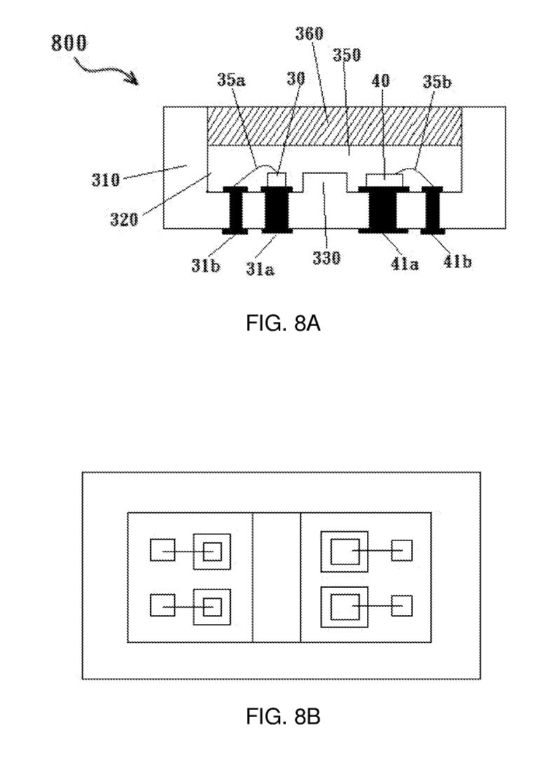

Optionally, referring to FIGS. 8A and 8B, the optocoupler 800 is a combination in which a plurality of light-emitting chips 30 control and correspond to a plurality of light-sensing chips 40 (not limited to two light-emitting chips 30 and two light-sensing chips 40), it has the capability of controlling a plurality of signal output terminals via a plurality of signal input terminals.

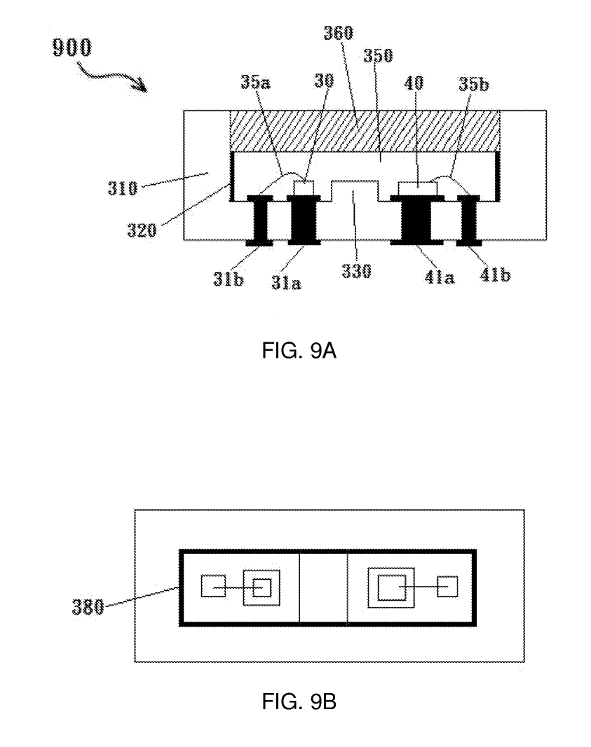

Optionally, referring to FIGS. 9A and 9B, on the optocoupler 900, a light reflective film 380 is provided on the side surface and the bottom surface of the recess 320 of the substrate 310. The light reflective film 380 has the capability of improving the optical coupling efficiency.

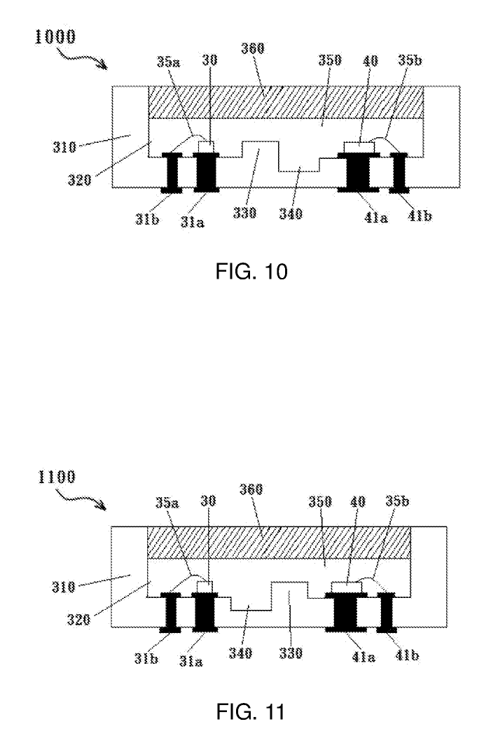

Optionally, referring to FIGS. 10 and 11, on the optocouplers 1000-1100, a combination of at least one concave portion 330 and at least one convex portion 340 is provided in the isolative structure within the recess 320 of the substrate 310. The at least one convex portion is adjacent to the at least one concave portion. The combination of the at least one concave portion 330 and the at least one convex portion 340 may increase a distance between the at least one light-emitting chip 30 and the at least one light-sensing chip 40 so as to achieve better high voltage isolative capability.

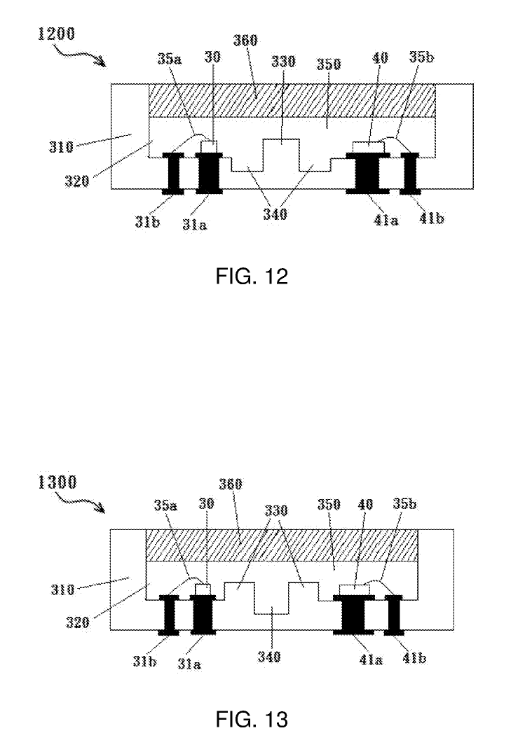

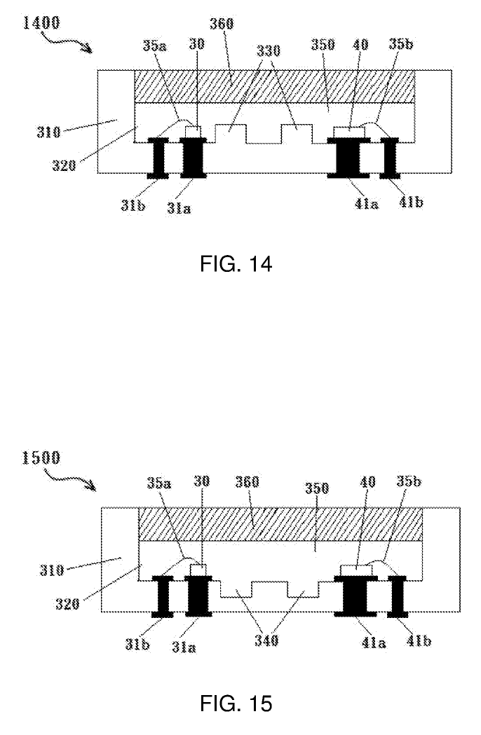

Optionally, referring to FIGS. 12-15, on the optocouplers 1200-1500, a variety of combinations of one or a plurality of concave portions 330 and one or a plurality of convex portions 340 are provided in the isolative structure within the recess 320 of the substrate 310. The convex portion is adjacent to the concave portion. The combinations of the one or a plurality of concave portions 330 and the one or a plurality of convex portions 340 may increase a distance between the at least one light-emitting chip 30 and the at least one light-sensing chip 40 so as to achieve better high voltage isolative capability.

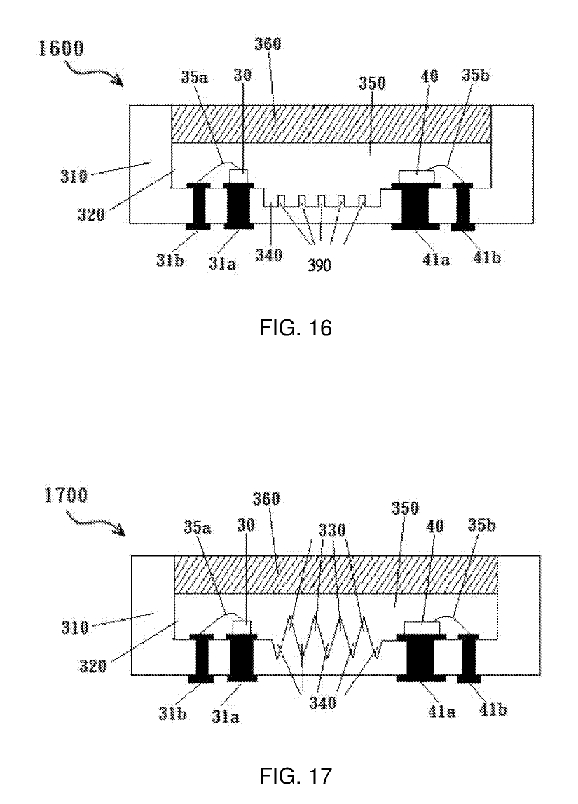

Optionally, referring to FIG. 16, on the optocoupler 1600, a combination of at least one concave portion 330 and at least one secondary convex 390 is provided in the isolative structure within the recess 320 of the substrate 310. The combination of the at least one concave portion 330 and the at least one secondary convex 390 may increase a distance between the at least one light-emitting chip 30 and the at least one light-sensing chip 40 so as to achieve better high voltage isolative capability.

Optionally, referring to FIG. 17, on the optocoupler 1700, cross-sectional shapes of the at least one convex portion and the at least one concave portion are triangles, quadrangles, or polygons. The specific shapes of the convex portion and the concave portion shown in the drawings are merely for illustration, which, in practice, can be adaptively changed according to specific requirements and are not limited herein.

Optionally, which, in practice, referring to FIGS. 3˜17, the at least one convex portion, the at least one concave portion, the at least one secondary convex and the substrate are integrally formed. Alternatively, the at least one convex portion and the at least one concave portion disclosed in FIGS. 10˜17 can be used in the optocouplers 300-900.

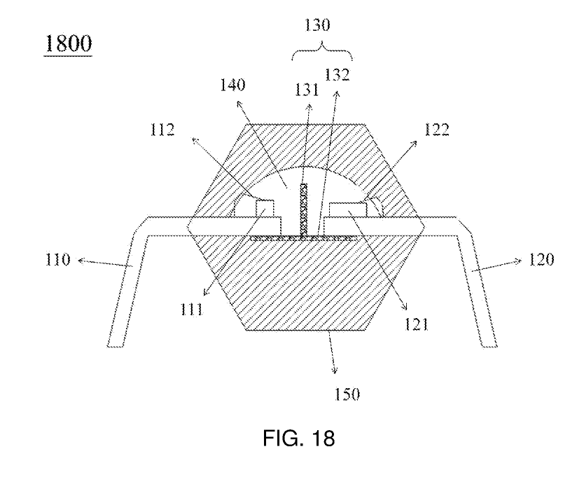

Referring to FIG. 18, the embodiment of the present disclosure provides an optocoupler. In the present embodiment, the isolative distance (Clearance) between a light-sensing chip and a light-emitting chip is improved by providing an isolative structure between at least one light-emitting chip and at least one light-sensing chip, so as to improve the conductive and electrical isolative function. The optocoupler includes:

at least one light-emitting chip 111 disposed at a first connective region 110 for emitting at least one invisible light;

at least one light-sensing chip 121 disposed at a second connective region 120 for receiving the at least one invisible light;

an isolative structure disposed between the at least one light-emitting chip 111 and the at least one light-sensing chip 121 for isolating an electric field, wherein the isolative structure includes a connective portion 132 and an isolative portion 131, and wherein the isolative structure is connected to the first connective region 110 and the second connective region 120 via the connective portion 132, so that the isolative portion 131 disposed at the connective portion 132 is located between the light-emitting chip 111 and the light-sensing chip 121;

a first encapsulant 140 covering the at least one light-emitting chip 111, the at least one light-sensing chip 121, the first connective region 110, the second connective region 120 and the isolative structure; and

a second encapsulant 150 covering the first encapsulant 140.

Specifically, the first connective region 110 can be a first conductive frame and the second connective region 120 can be a second conductive frame. An elliptical structure is formed with the first encapsulant 140 covering the first connective region 110, the light-emitting chip 111, the second connective region 120, the light-sensing chip 121, and the isolative structure, wherein the light-emitting chip 111 and the light-sensing chip 121 are respectively disposed at two focuses of the elliptical structure of the first encapsulant 140. The first encapsulant 140 fully covers the at least one light-emitting chip 112 and the at least one light-sensing chip 122, and has high light transmittance, thereby increasing the light coupling efficiency of the optocoupler 1800, and has a function of protecting the at least one light-emitting chip 112 and the at least one light-sensing chip 122. For example, a material of the first encapsulant 140 can be polyimide (PI) or silicone. The second encapsulant 150 surrounds the first encapsulant 140 and the material of the second encapsulant 150 can be a black encapsulant or a white encapsulant. In an embodiment of the present disclosure, a material of the second encapsulant 150 is different from the material of the first encapsulant 140. For example, the material of the second encapsulant 150 includes epoxy, which has characteristics of, for example, high light reflectivity, water blocking property, gas barrier property, isolative property and mechanical strength, etc. The at least one light-emitting chip 112 includes an infrared light-emitting diode (LED), a gallium nitride (GaN) base LED, an aluminum gallium arsenide (AlGaAs) LED or a gallium arsenide phosphide (GaAsP) LED; and the at least one light-sensing chip 122 includes a photo diode, a photo transistor, a photo darlington transistor, a photo tryristor, a photo bidirectional thyristor, or a photo integrated circuit.

In the present embodiment, a material of the isolative structure is a semi-transmissive material, a mirror material, a selective wavelength mirror optical material, a thermally-sensitive material including vanadium dioxide, or a transparent isolative material including polyimide. In another preferred embodiment, the isolative structure can be of a multi-layer structure including a variety of combinations of the above materials.

Optionally, the isolative portion 131 is perpendicularly disposed at the connective portion 132, and a perpendicular height of the isolative portion 131 extending from the connective portion 132 is not greater than a thickness of the first encapsulant 140.

Optionally, the connective portion 132 is further made of an adhesive material, and the isolative portion 131 is made of a transparent isolative material including polyimide.

Optionally, the connective portion 132 further includes a first connective portion 132a and a second connective portion 132b, wherein the isolative portion 131 is disposed between the first connective portion 132a and the second connective portion 132b in advance, wherein the first connective portion 132a and the second connective portion 132b are respectively connected to the first connective region 110 and the second connective region 120 in such a way that the isolative portion 131 is located between the light-emitting chip 111 and the light-sensing chip 121, and wherein the first connective portion 132a, the second connective portion 132b and the isolative portion 131 are integrally molded in sequence.

In the present embodiment, the electric filed effect from both of the input terminal and the output terminal can be isolated by providing the isolative structure between the at least one light-emitting chip 111 and the at least one light-sensing chip 121. Meanwhile, the protruded isolative structure can effectively assist the encapsulant in forming an ellipse. By taking advantage of the characteristics of the ellipse that a light is emitted from one elliptical focus and converges to another elliptical focus after reflection, the characteristics of the component can be improved.

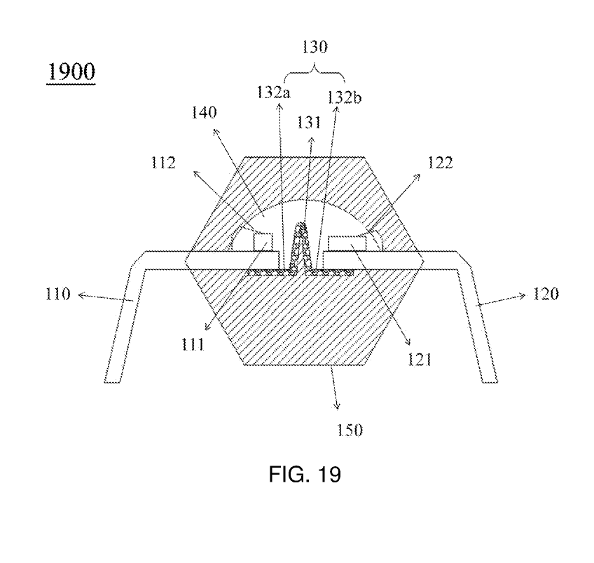

Optionally, referring to FIGS. 18 and 19, the isolative portion 131 can be a cube or a cone, which is a shape easy to bend. The isolative portion 131 formed by a flexible film in advance can also be a V-shaped structure, and perpendicular to the first connective portion 132a and the second connective portion 132.

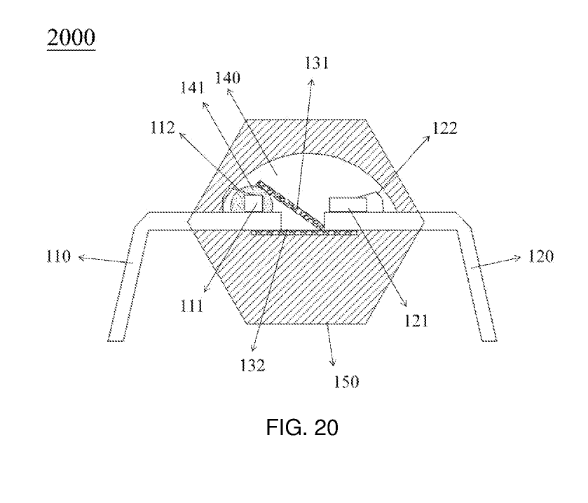

Optionally, referring to FIG. 20, the isolative portion 131 is obliquely disposed at the connective portion 132. The optocoupler 2000 further includes a third encapsulant 141 made of a light-transparent material for covering one of the light-emitting chip 111 or the light-sensing chip 121, so that the oblique isolative portion 131 is disposed at the third encapsulant 141 simultaneously, wherein the first encapsulant 140 covers the third encapsulant 141. The isolative portion 131 is provided within the third encapsulant 141 in advance, and can thus be steadily fixed within the optocoupler.

The foregoing descriptions are merely exemplary embodiments of the present disclosure, but not intended to limit the present disclosure. Any modification, equivalent replacement, or improvement made without departing from the spirit and principle of the present disclosure should fall within the protection scope of the present disclosure.

What is claimed is:

1. An optocoupler, comprising:
at least one light-emitting chip disposed at a first connective region for emitting at least one invisible light;
at least one light-sensing chip disposed at a second connective region for receiving the at least one invisible light;
an isolative structure disposed between the at least one light-emitting chip and the at least one light-sensing chip for isolating an electric field;
a first encapsulant covering the at least one light-emitting chip, the at least one light-sensing chip, the first connective region, the second connective region and the isolative structure;
a second encapsulant covering the first encapsulant; and
a substrate having a recess;
wherein the first connective region and the second connective region are disposed within the substrate and have conductive characteristic, the at least one light-emitting chip is disposed within the recess and electrically connected with the first connective region being a signal input terminal, the at least one light-sensing chip is disposed within the recess and electrically connected with the second connective region being a signal output terminal, and the first encapsulant and the second encapsulant are disposed within the recess.

2. The optocoupler according to claim 1, wherein the isolative structure comprises: at least one convex portion and/or at least one concave portion disposed on the recess, wherein a height of the at least one convex portion is not greater than one-half of a height of the first encapsulant, and a height of the at least one concave portion is not greater than one-half of a thickness of the substrate.

3. The optocoupler according to claim 2, wherein the recess comprises a bottom surface and a side surface provided with a reflective layer, wherein the side surface surrounds the bottom surface, and the at least one light-emitting chip and the at least one light-sensing chip are disposed at the bottom surface.

4. The optocoupler according to claim 2, wherein,
the first encapsulant is formed of a highly transparent material comprising polyimide, PI, or silicone;
the second encapsulant is formed of a reflective material comprising epoxy;
a material of the substrate is a non-metal material comprising a silicon substrate or a glass substrate;
the at least one light-emitting chip comprises an infrared light-emitting diode, LED, a gallium nitride, GaN, base LED, an aluminum gallium arsenide, AlGaAs, LED or a gallium arsenide phosphide, GaAsP, LED; and
the at least one light-sensing chip comprises a photo diode, a photo transistor, a photo darlington transistor, a photo tryristor, a photo bidirectional thyristor or a photo integrated circuit.

5. The optocoupler according to claim 2, wherein
when the isolative structure comprises the at least one convex portion and the at least one concave portion, the at least one convex portion is adjacent to the at least one concave portion.

6. The optocoupler according to claim 2, wherein cross-sectional shapes of the at least one convex portion and the at least one concave portion are triangles, quadrangles, or polygons.

7. The optocoupler according to claim 2, wherein when the isolative structure comprises the at least one convex portion and the at least one concave portion, the at least one convex portion is at least one secondary convex portion disposed within the at least one concave portion.

8. An optocoupler, comprising:
at least one light-emitting chip disposed at a first connective region for emitting at least one invisible light;
at least one light-sensing chip disposed at a second connective region for receiving the at least one invisible light;
an isolative structure disposed between the at least one light-emitting chip and the at least one light-sensing chip for isolating an electric field, wherein the isolative structure comprises a connective portion and an isolative portion, and the isolative structure is connected to the first connective region and the second connective region via the connective portion in such a way that the isolative portion disposed at the connective portion is located between the light-emitting chip and the light-sensing chip;
a first encapsulant covering the at least one light-emitting chip, the at least one light-sensing chip, the first connective region, the second connective region and the isolative structure; and
a second encapsulant covering the first encapsulant.

9. The optocoupler according to claim 8, wherein the connective portion is made of an adhesive material, and the isolative portion is made of a transparent isolative material comprising polyimide.

10. The optocoupler according to claim 8, wherein the isolative portion is perpendicularly disposed at the connective portion, and a perpendicular height of the isolative portion extending from the connective portion is not greater than a thickness of the first encapsulant, and the isolative portion is a cube or a cone.

11. The optocoupler according to claim 8 wherein the isolative portion is obliquely disposed at the connective portion.

12. The optocoupler according to claim 8, wherein the connective portion further comprises a first connective portion and a second connective portion, wherein the isolative portion is disposed between the first connective portion and the second connective portion in advance, wherein the first connective portion and the second connective portion are respectively connected to the first connective region and the second connective region in such a way that the isolative portion is located between the light-emitting chip and the light-sensing chip, and wherein the first connective portion, the second connective portion and the isolative portion are integrally molded in sequence.

13. The optocoupler according to claim 8, wherein the first encapsulant covers the first connective portion, the light-emitting chip, the second connective portion, the light-sensing chip and the isolative structure to form an elliptical structure, wherein the light-emitting chip and the light-sensing chip are respectively disposed at two focuses of the elliptical structure of the first encapsulant.

14. The optocoupler according to claim 11, further comprising a third encapsulant made of a light-transparent material for covering one of the light-emitting chip or the light-sensing chip, so that the oblique isolative portion is disposed at the third encapsulant simultaneously, wherein the first encapsulant covers the third encapsulant.

15. The optocoupler according to claim 13, wherein the isolative portion formed in advance is a V-shaped structure, and perpendicular to the first connective portion and the second connective portion.
